(19) United States
(12) Patent Application Publication
(10) Pub. No.: US 2018/0277234 A1
(43) Pub. Date: Sep. 27, 2018

(54) FAILURE PREVENTION OF BUS MONITOR

(71) Applicant: MEDIATEK INC., Hsin-Chu (TW)

(72) Inventor: Jeendar HUANG, Zhubei City (TW)

(21) Appl. No.: 15/722,617

(22) Filed: Oct. 2, 2017

Related U.S. Application Data
(60) Provisional application No. 62/475,940, filed on Mar. 24, 2017.

(51) Int. Cl. G11C 29/12; G06F 13/16

(52) U.S. Cl. CPC G11C 29/1201; G11C 2029/1806; G11C 2029/1208; G06F 13/1694

(57) ABSTRACT

A test controller is provided. The test controller includes: a test circuit and a bus monitor. The test circuit is for testing the functionality of a bus apparatus, wherein the bus apparatus includes a bus connected between a bus agent and a first bus matrix. The bus monitor is for monitoring bus signals on an interface of the bus. When a test is enabled during operation of the bus apparatus, the test circuit saves the statuses and configurations of the bus apparatus that are extracted from the bus signals into a memory. When the test is completed, the test circuit restores the statuses and configurations of the bus apparatus from the memory.

### CROSS REFERENCE TO RELATED APPLICATIONS

This application claims the benefit of U.S. Provisional Application No. 62/475,940, filed at Mar. 24, 2017, the entirety of which is incorporated by reference herein.

### BACKGROUND OF THE INVENTION

### Field of the Invention

The present invention relates to semiconductor devices, and, in particular, to a test controller and an associated test method for providing a failure prevention mechanism for a bus monitor.

### Description of the Related Art

There are many known semiconductor integrated circuits (LSIs) that have a BIST (built-in self-test) circuit for conducting a self-test. Upon the start of a test, the BIST circuit generates test patterns and supplies these to a test subject circuit, such as a memory circuit or a logic circuit. The BIST circuit judges whether the test subject circuit is defective or not by comparing the test results of the test subject circuit with expected values.

In a conventional BIST circuit of an integrated circuit, a bus monitor is often used to monitor bus signals on the interface of the bus. However, the conventional BIST circuit is not designed to guarantee the reliability of the bus monitor. If the bus monitor is not working properly, the BIST result may be erroneous. Furthermore, a conventional BIST is performed when the integrated circuit is not in operation, and thus it is difficult for system operation to know whether the bus in the integrated circuit works properly when the integrated circuit is operating.

Therefore, there is a need for a test controller and an associated BIST method that can solve the above-mentioned problems.

### BRIEF SUMMARY OF THE INVENTION

A detailed description is given in the following embodiments with reference to the accompanying drawings.

In an exemplary embodiment, a test controller is provided. The test controller includes a test circuit and a bus monitor. The test circuit is for testing the functionality of a bus apparatus, wherein the bus apparatus comprises a bus connected between a bus agent and a first bus matrix. The bus monitor is for monitoring bus signals on an interface of the bus. When a test is enabled during operation of the bus apparatus, the test circuit saves statuses and configurations of the bus apparatus that are extracted from the bus signals into a memory. When the test is completed, the test circuit restores the statuses and configurations of the bus apparatus from the memory.

In another exemplary embodiment, a test method for use in a test controller is provided. The test controller includes a test circuit for testing the functionality of a bus apparatus; and a bus monitor, for monitoring bus signals on an interface of the bus, wherein the bus apparatus comprises a bus connected between a bus agent and a first bus matrix. The method includes the following steps: when a test is enabled during operation of the bus apparatus, utilizing the test circuit to save statuses and configurations of the bus apparatus that are extracted from the bus signals into a memory, and when the test is completed, utilizing the test circuit to restore the statuses and configurations of the bus apparatus from the memory.

In yet another exemplary embodiment, a test controller is provided. The test controller includes: a test circuit configured to test functionality of a bus apparatus; and a bus monitor, for monitoring bus signals on an interface of a bus of the bus apparatus. The test circuit is further configured to detect a status of the bus monitor, and determine whether to raise an alarm signal according to the status of the bus monitor.

### BRIEF DESCRIPTION OF THE DRAWINGS

The present invention can be more fully understood by reading the subsequent detailed description and examples with references made to the accompanying drawings, wherein:

FIG. 1 is a block diagram of a bus system in accordance with an embodiment of the invention;

FIG. 2 is a diagram of the operations performed by the bus monitoring device in accordance with an embodiment of the invention;

FIG. 3 is a detailed schematic diagram of the bus monitoring device in accordance with an embodiment of the invention;

FIG. 4 is a diagram of the operation of the bus system in accordance with an embodiment of the invention;

FIG. 5 is a diagram of the operation of the bus system in accordance with another embodiment of the invention;

FIG. 6 is a diagram of the operation of the bus system in accordance with yet another embodiment of the invention;

FIG. 7 is a diagram of the operation of the bus system in accordance with yet another embodiment of the invention; and

FIG. 8 is a flow chart of a test method in accordance with an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

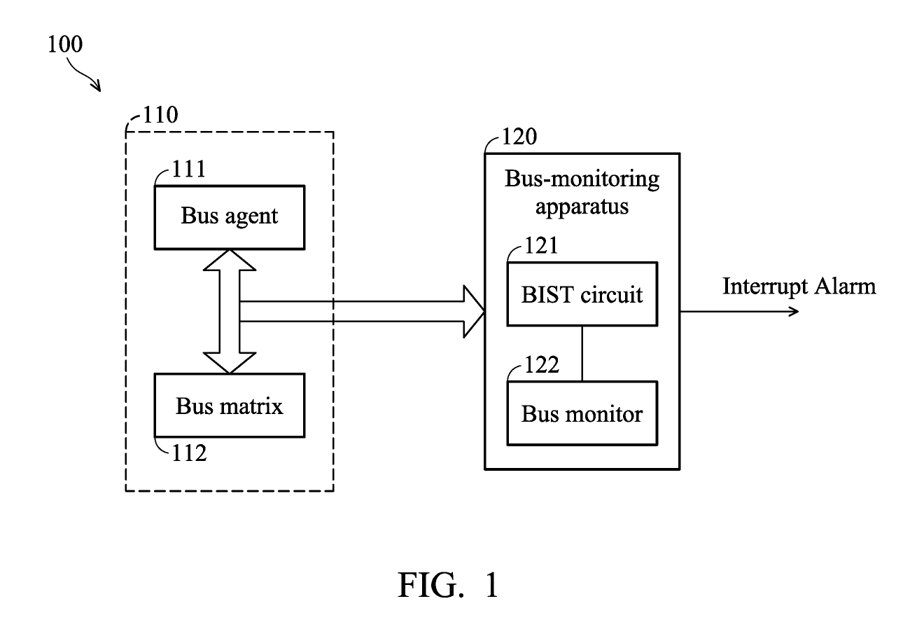

FIG. 1 is a block diagram of a bus system in accordance with an embodiment of the invention. As illustrated in FIG. 1, the bus system 100 includes a bus apparatus 110 and a bus-monitoring apparatus 120. The bus apparatus 110 can be employed into an electronic device that is used to inter-communicate each component in the electronic device. The bus-monitoring apparatus 120 is configured to test and monitor the functionality of the bus apparatus 110, and thus can be regarded as a test controller.

For example, the bus apparatus 110 includes one or more bus agents 111, a bus matrix 112, and a bus 113. The bus agent 111 and the bus matrix 112 communicate with each other via the bus 113. Specifically, the bus 113 may include one or more electrical circuits that are used to connect and transmit data between devices connected to the bus. The bus agent 111 may be a device that initiates and/or controls transactions of a bus interface. For example, the bus agent 111 may be a master device or a client device.

The bus matrix 112 is a shared interconnecting circuit used to connect multiple devices, and the bus matrix 112 is capable of deciding the arbitration transaction between an initiator agent and its associated receiving agent. It should be noted that the aforementioned initiator agent and the associated responding agent are among the devices that are connected to the bus 113. For example, an initiator agent may be a central processing unit (CPU) and the associated responding agent may be a peripheral device connected to the bus 113.

It should be noted that BIST is a mechanism that permits a machine to test itself, and engineers design BISTs to meet requirement such as high reliability and lower repair cycle times, or meet constraints such as limited technician accessibility and cost of testing during manufacture. For example, the BIST is widely used in the fields of weapons, avionics, medical devices, automotive electronics, complex machinery, and integrated circuits. In the field of integrated circuit (IC) manufacturing, BIST is used to make faster, less-expensive integrated circuit tests. The IC has a function that verifies all or a portion of the internal functionality of the IC.

The bus-monitoring apparatus 120 includes a test circuit, which may be a built-in self-test (BIST) circuit 121 as an example, and a bus monitor 122. The bus monitor 122 is a circuit that listens on the interface of the bus 113 and intercepts a copy of the messages on the interface of the bus 113. The BIST circuit 121 is a testing circuit that permits the electronic device employed with the bus apparatus 110 and the bus-monitoring apparatus 120 to test itself. The BIST circuit 121 is also configured to detect the status of the bus monitor 122. Specifically, the bus monitor 122 may be malfunctioned due to various conditions such as component aging, high operation temperature, and/or erroneous configurations of the bus apparatus 110.

In an embodiment, the bus-monitoring apparatus 120 is capable of performing on-the-fly self-health checking when the bus agent 111 is busy. In addition, the bus-monitoring apparatus 120 may be configured to monitor functions of the bus apparatus 110 such as legal or illegal transaction address boundaries, transaction types, transaction duration, transaction time-out, transaction address hit assertion, and/or qualification of the byte alignment assertion. The bus-monitoring apparatus 120 is also capable of raising an alarm caused by detected abnormal bus behaviors. For example, the alarm may meet the requirements by software configuration, and the bus-monitoring apparatus 120 is also capable of on-the-fly reconfiguring of the configurations of the bus 113.

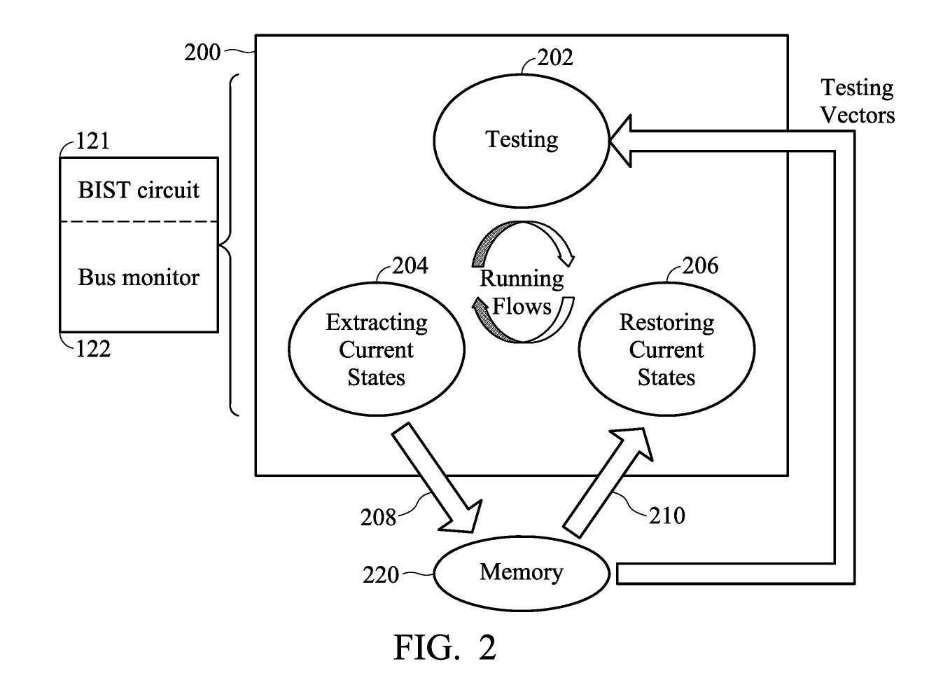

FIG. 2 is a diagram of the operations performed by the bus monitoring device in accordance with an embodiment of the invention.

In an embodiment, the BIST circuit 121 is capable of extracting current states from the bus detection signal from the bus monitor 122, perform BIST using pre-stored BIST vectors, and restoring the current states of the bus apparatus 110. Specifically, in block 204, the BIST circuit 121 extracts current states from the bus detection signal from the bus monitor 122, and push the extracted states into the memory 123 (arrow 208). Then, in block 202, the BIST circuit 121 performs BIST using the test vectors stored in the memory 123. If the BIST passes, it indicates that the functionalities of the bus apparatus 110 and the bus monitor 122 are normal, and thus the BIST circuit 121 may then restore the current states stored in the memory 123 to the bus apparatus 110, so that the bus apparatus 110 may keep running during the BIST duration. If the BIST results in a failure, it indicates that the functionalities of the bus apparatus 110 and/or the bus monitor 122 are abnormal, and thus the BIS circuit 121 may raise an interrupt to the CPU and software processes, and the CPU may determine how to handle the bus abnormal behaviors.

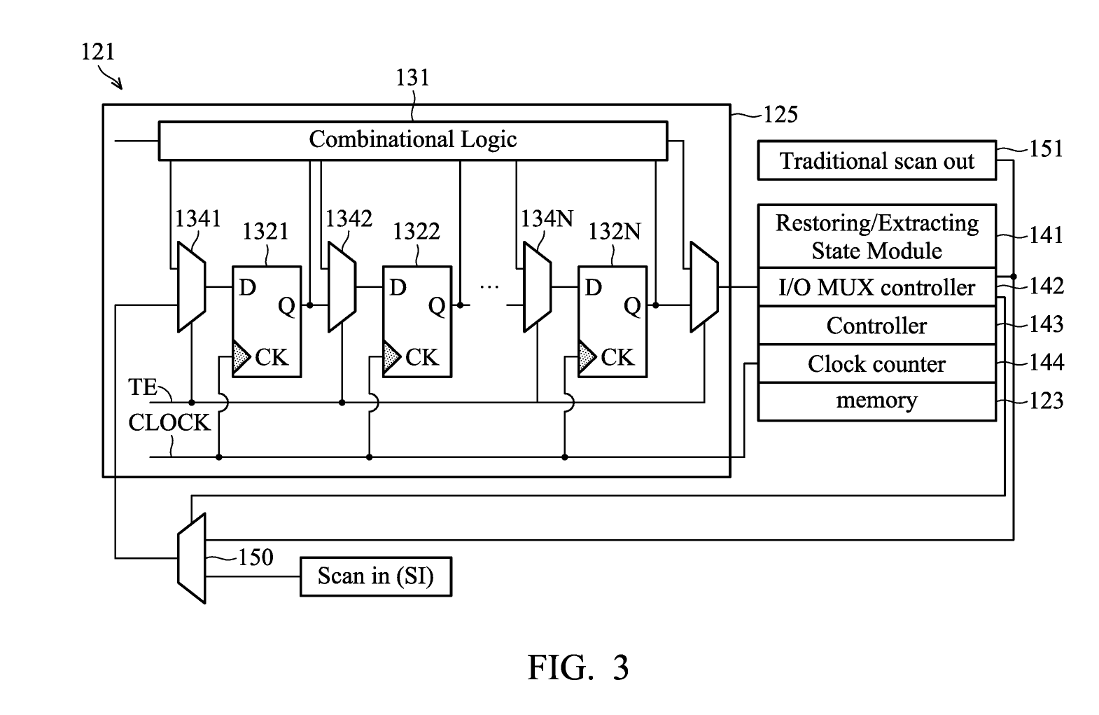

FIG. 3 is a detailed schematic diagram of the BIST circuit in accordance with an embodiment of the invention.

As illustrated in FIG. 3, the BIST circuit 121 includes scan logic 125, a restoring/extracting state module 141, an I/O MUX controller 142, a controller 143, a block counter 144, and a memory 123. For example, the scan logic 125 may include a combinational logic 131 that is connected to a plurality of multiplexers 1341-134N and D flip-flops 1321-132N. The BIST function of the BIST circuit 121 can be enabled by the TE signal. One having ordinary skill in the art will appreciate the design of the scan logic 125, and thus the details of the scan logic will be omitted here.

The input signal of the BIST can be selected from the scan-in (SI) signal or the extracted status signal. For example, the SI signal may be generated from external automatic test equipment (ATE), and the traditional BIST can be performed when the SI signal is selected.

The extracted status signal can be retrieved from the RAM 123 by the controller 143 through the I/O MUX controller 142. When the BIST is performed on-the-fly (i.e. the device employed with the bus apparatus 110 is operating), the traditional BIST using external ATE cannot be used. In this situation, the controller 143 retrieves the extracted status signal that was previously extracted, by the restoring/extracting state module 141, from the bus detection signal from the bus monitor 122. Then, the controller 143 may control the multiplexer 150 to select the pre-stored test vectors (i.e. traditional scan out 151) as the input of the scan chain of the scan logic 125.

The clock counter 144 is configured to count the clock cycles of the clock signal CLOCK. For example, while performing the on-the-fly BIST, the bus apparatus 110 is still running. Thus, the duration for the on-the-fly BIST should be precisely calculated, thereby facilitating the restoration of the statuses of the bus apparatus 110 later.

More specifically, the components 141˜144 and 150 can be implemented as additional circuits to the scan logic 125 which may be a traditional scan logic. Furthermore, the complexity of the components 141˜144 and 150 is low, and thus these components has a very limited impact on the legacy design code of the traditional BIST circuit.

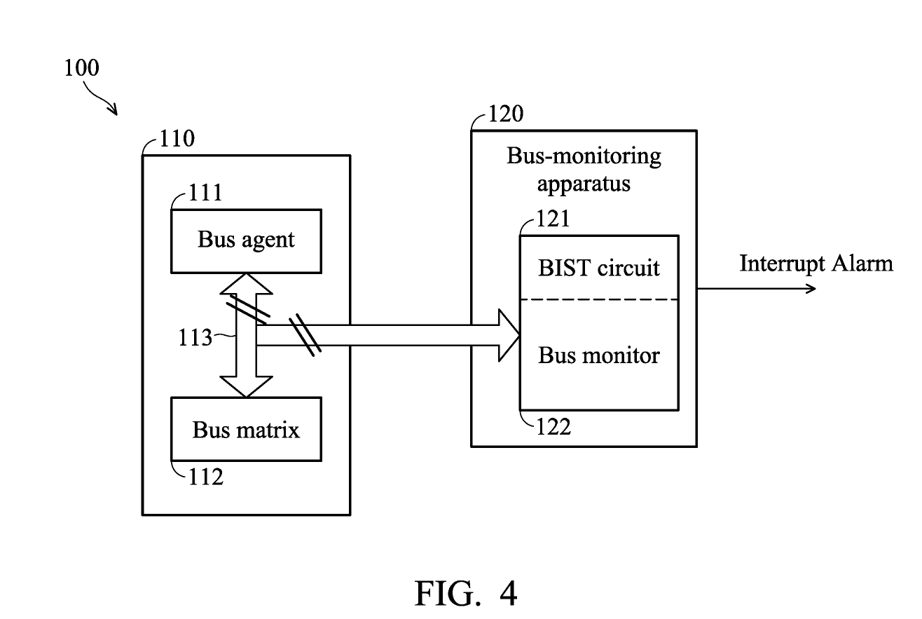

FIG. 4 is a diagram of the operation of the bus system in accordance with an embodiment of the invention.

In an embodiment, it may take time to perform the on-the-fly BIST after the BIST function is enabled during operation of the bus apparatus 110. Since the bus apparatus 110 is operating, the signals on the interface of the bus 113 vary time to time. In the first scenario, the BIST circuit 121 may issue a control signal to the bus matrix 112, so that the bus matrix 112 may control the bus 113 to pause for a time period. Thus, there will be no bus activity on the interface of the bus 113 during the time period. It should be noted that the time period can be adjust according to practical needs.

More specifically, after the BIST function is enabled during operation of the bus apparatus 110, the bus monitor 122 may immediately capture the bus signals on the interface of the bus 113, and the captured bus signals are extracted and saved into the memory 123 by the restoring/extracting state module 141. Then, the BIST circuit 121 may issue a control signal to the bus matrix 112 and the bus 113, so that the bus 113 pauses for a time period. Then, the BIST circuit 121 may perform the on-the-fly BIST according to pre-stored test vectors to determine whether the bus behaviors of the bus apparatus 110 and the bus monitor 122 are normal.

If the bus behaviors of the bus apparatus 110 and the bus monitor 122 are normal, it indicates that health of the bus apparatus 110 and the bus monitor 122 is in a good condition, and the controller 143 may control the restoring/extracting state module 141 to restore the bus statuses of the bus apparatus 110 with the previously captured bus signals. After restoration of the bus statuses of the bus apparatus 110 is completed, the BIST circuit 121 may issue another control signal to the bus matrix 112 to control the bus 113 to operate again.

If the bus behaviors of the bus apparatus 110 and/or the bus monitor 122 are not normal, it indicates that a problem may happen to the bus apparatus 110 and/or the bus monitor 122, and the BIST circuit 121 may send an interrupt signal (i.e. an alarm signal) to the CPU and software processes to inform the bus failure condition, so that the CPU may take appropriate actions on the bus failure condition. The controller 143 may control the restoring/extracting state module 141 to restore the bus statuses of the bus apparatus 110 with the previously captured bus signals. After restoration of the bus statuses of the bus apparatus 110 is completed, the BIST circuit 121 may issue another control signal to the bus matrix 112 to control the bus 113 to operate again.

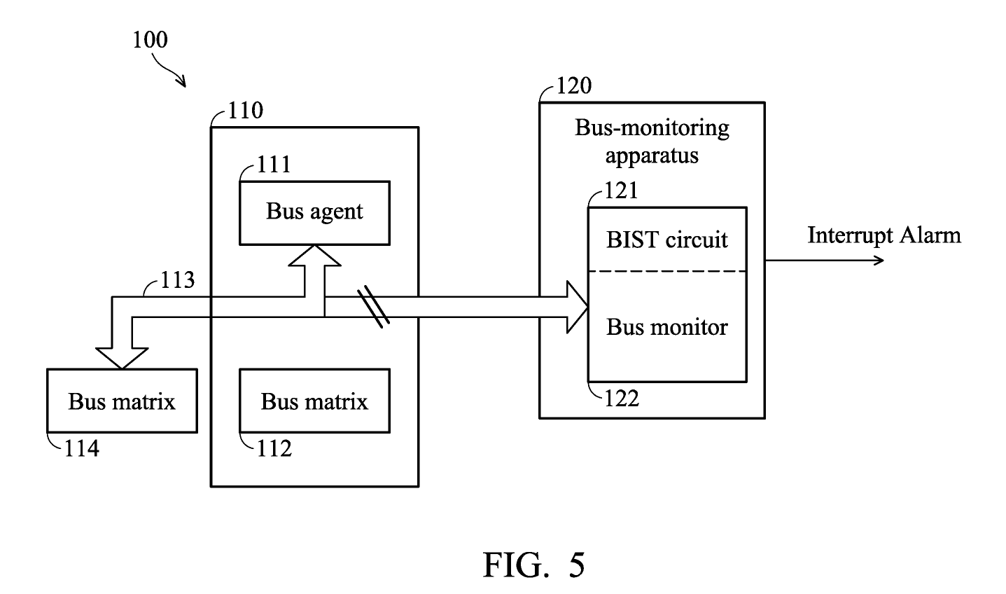

FIG. 5 is a diagram of the operation of the bus system in accordance with another embodiment of the invention.

In the second scenario, the BIST circuit 121 may issue a control signal to the bus matrix 112, so that the bus matrix 112 may control the bus 113 to re-park its bus interface to a reserved bus interface of a bus matrix 114 for a time period. Thus, the bus matrix 114 may be a temporary bus matrix to substitute the functionality of the bus matrix 112 for the time period, and the original bus interface between the bus 113 and the bus matrix 112 is also paused for the time period. It should be noted that the time period can be adjust according to practical needs.

More specifically, after the BIST function is enabled during operation of the bus apparatus 110, the bus monitor 122 may immediately capture the bus signals on the interface of the bus 113, and the captured bus signals are extracted and saved into the memory 123 by the restoring/extracting state module 141. Then, the BIST circuit 121 may issue a control signal to the bus matrix 112 and the bus 113, so that the bus interface between the bus 113 and the bus matrix 112 is paused for the time period. Meanwhile, the interface of the bus 113 is directed to the reserved interface of the bus matrix 114. Then, the BIST circuit 121 may perform the on-the-fly BIST according to pre-stored test vectors to determine whether the bus behaviors of the bus apparatus 110 and the bus monitor 122 are normal.

If the bus behaviors of the bus apparatus 110 and the bus monitor 122 are normal, it indicates that health of the bus apparatus 110 and the bus monitor 122 is in a good condition, and the controller 143 may control the restoring/extracting state module 141 to restore the bus statuses of the bus apparatus 110 with the previously captured bus signals. After restoration of the bus statuses of the bus apparatus 110 is completed, the BIST circuit 121 may issue another control signal to the bus matrix 112 to control the interface of the bus 113 to be directed to the bus matrix 112 and disable the bus matrix 114.

If the bus behaviors of the bus apparatus 110 and/or the bus monitor 122 are not normal, it indicates that a problem may happen to the bus apparatus 110 and/or the bus monitor 122, and the BIST circuit 121 may send an interrupt signal (i.e. an alarm signal) to the CPU and software processes to inform the bus failure condition, so that the CPU may take appropriate actions on the bus failure condition. The controller 143 may control the restoring/extracting state module 141 to restore the bus statuses of the bus apparatus 110 (i.e. bus agent 111, bus matrix 112, and bus 113) with the previously captured bus signals. After restoration of the bus statuses of the bus apparatus 110 is completed, the BIST circuit 121 may issue another control signal to the bus matrix 112 and the bus 113, so that the interface of the bus 113 is directed to the original bus interface between the bus 113 and the bus matrix 112, and the bus 113 is operated again with the bus matrix 112.

In some embodiments, if the bus behaviors of the bus apparatus 110 and the bus monitor 122 are not normal, the functionality of the bus matrix 112 will be replaced by the bus matrix 114.

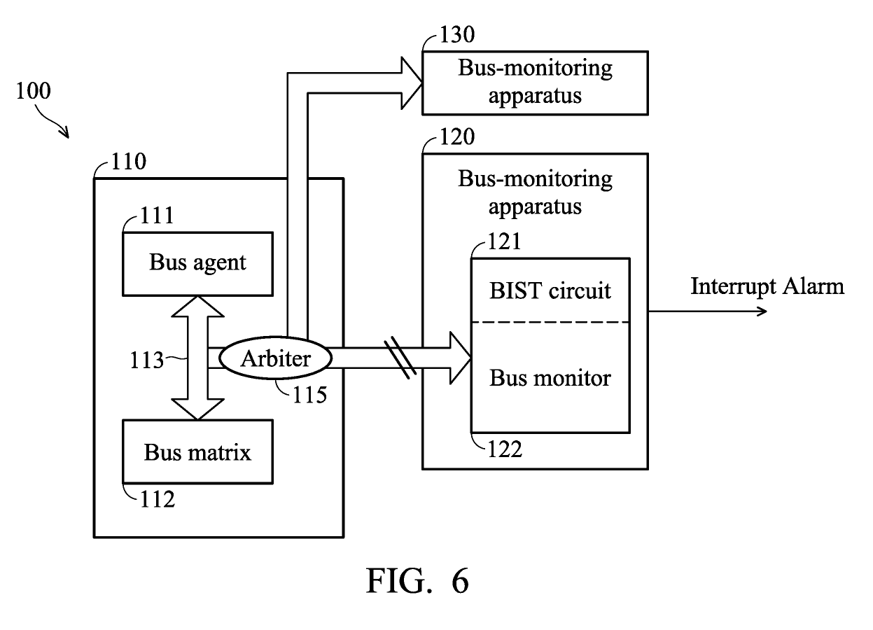

FIG. 6 is a diagram of the operation of the bus system in accordance with yet another embodiment of the invention.

In the third scenario, the bus apparatus 110 further includes an arbiter 115. The arbiter 115 is configured to direct the monitoring interface to connect to another bus-monitoring apparatus 130 and the original monitoring interface from the bus 113 to the bus monitor 122 is paused. The components in the bus-monitoring apparatus 130 are similar to those in the bus-monitoring apparatus 120.

For example, the BIST circuit 121 may issue a control signal to the arbiter 115, so that arbiter 115 may direct the monitoring interface to another bus-monitoring apparatus 130 and control the monitoring interface from the bus 113 to the bus monitor 122 to pause for a time period. Thus, the bus-monitoring apparatus 130 may temporarily substitute the functionality of the bus-monitoring apparatus 120 for the time period, and the original monitoring interface from the bus 113 to the bus monitor 122 is also paused for the time period. It should be noted that the time period can be adjust according to practical needs.

More specifically, after the BIST function is enabled during operation of the bus apparatus 110, the bus monitor 122 may immediately capture the bus signals on the interface of the bus 113, and the captured bus signals are extracted and saved into the memory 123 by the restoring/extracting state module 141. Then, the BIST circuit 121 may issue a control signal to the arbiter 115 to control the monitoring interface between the bus 113 and the bus monitor 122 to pause for the time period. Meanwhile, the monitoring interface is directed to the bus-monitoring apparatus 130 by the arbiter 115. Then, the BIST circuit 121 may perform the on-the-fly BIST according to pre-stored test vectors to determine whether the bus behaviors of the bus apparatus 110 and the bus monitor 122 are normal.

If the bus behaviors of the bus apparatus 110 and the bus monitor 122 are normal, it indicates that health of the bus apparatus 110 and the bus monitor 122 is in a good condition, and the controller 143 may control the restoring/extracting state module 141 to restore the bus statuses of the bus apparatus 110 with the previously captured bus signals. After restoration of the bus statuses of the bus apparatus 110 is completed, the BIST circuit 121 may issue another control signal to the arbiter 115 to control the interface of the bus 113 to be directed to the bus matrix 112 and disable the bus matrix 114.

If the bus behaviors of the bus apparatus 110 and/or the bus monitor 122 are not normal, it indicates that a problem may happen to the bus apparatus 110 and/or the bus monitor 122, and the BIST circuit 121 may send an interrupt signal (i.e. an alarm signal) to the CPU and software processes to inform the bus failure condition, so that the CPU may take appropriate actions on the bus failure condition. The controller 143 may control the restoring/extracting state module 141 to restore the bus statuses of the bus apparatus 110 (i.e. bus agent 111, bus matrix 112, and bus 113) with the previously captured bus signals. After restoration of the bus statuses of the bus apparatus 110 is completed, the BIST circuit 121 may issue another control signal to the arbiter 115, so that the monitoring interface is directed to the original monitoring interface between the bus 113 and the bus monitor 112.

In some embodiments, if the bus behaviors of the bus apparatus 110 and the bus monitor 122 are not normal, it may indicate that there may be a problem with the bus monitor 122, and the functionality of the bus-monitoring apparatus 120 will be replaced by the bus-monitoring apparatus 130.

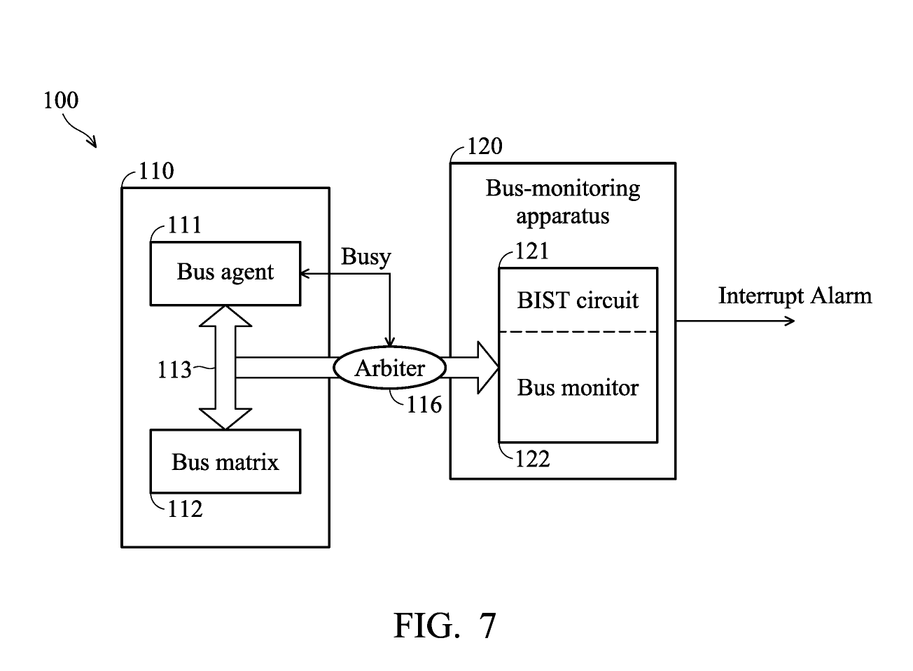

FIG. 7 is a diagram of the operation of the bus system in accordance with yet another embodiment of the invention.

In the fourth scenario, the bus apparatus 110 further includes an arbiter 116. The arbiter 116 is configured to receive a busy notification signal from the bus agent 111, and inform the bus monitor 122 of the busy state of the bus agent 111. If the bus agent 111 issues the busy notification signal to the arbiter 116 and the bus monitor 122 is informed of the busy state of the bus agent 111, the bus monitor 112 may temporarily disable the bus-monitoring function until the BIST is ready and the bus agent 111 is not in the busy state.

More specifically, if the bus agent 111 is not in the busy state after the BIST function is enabled during operation of the bus apparatus 110, the bus monitor 122 may immediately capture the bus signals on the interface of the bus 113, and the captured bus signals are extracted and saved into the memory 123 by the restoring/extracting state module 141. Then, the BIST circuit 121 may perform the on-the-fly BIST according to pre-stored test vectors to determine whether the bus behaviors of the bus apparatus 110 and the bus monitor 122 are normal. If the bus agent 111 is in the busy state after the BIST function is enabled during operation of the bus apparatus 110, the arbiter 116 may receive the busy notification signal from the bus agent 111, and the bus monitor 122 is informed of the busy state of the bus agent. Then, the bus monitor 122 may temporarily disable the bus-monitoring function until the BIST is ready and the bus agent 111 is not in the busy state.

In other words, if the BIST is being performed or the bus agent 111 is in the busy state, the bus monitor 122 may temporarily disable the bus-monitoring function. When the BIST is ready (i.e. not being performed) and the bus agent 111 is not in the busy state, the bus monitor 122 may restore the bus-monitoring function.

If the bus behaviors of the bus apparatus 110 and the bus monitor 122 are normal, it indicates that health of the bus apparatus 110 and the bus monitor 122 is in a good condition, and the controller 143 may control the restoring/extracting state module 141 to restore the bus statuses of the bus apparatus 110 with the previously captured bus signals. After restoration of the bus statuses of the bus apparatus 110 is completed, the bus monitor 122 may be recovered to the normal state.

If the bus behaviors of the bus apparatus 110 and the bus monitor 122 are not normal, it indicates that a problem may happen to the bus apparatus 110 and/or the bus monitor 122, and the BIST circuit 121 may send an interrupt signal (i.e. an alarm signal) to the CPU and software processes to inform the bus failure condition, so that the CPU may take appropriate actions on the bus failure condition. The controller 143 may control the restoring/extracting state module 141 to restore the bus statuses of the bus apparatus 110 (i.e. bus agent 111, bus matrix 112, and bus 113) with the previously captured bus signals. After restoration of the bus statuses of the bus apparatus 110 is completed, the bus monitor 122 may be recovered to the normal state.

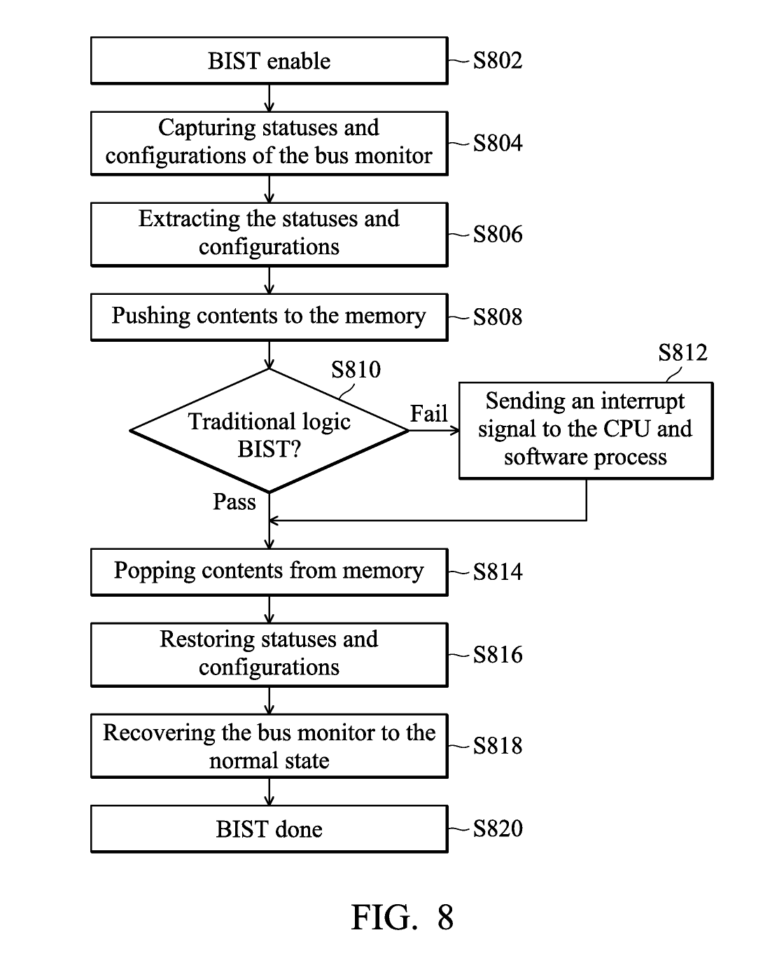

FIG. 8 is a flow chart of a test method in accordance with an embodiment of the invention.

In step S802, BIST is enabled.

In step S804, statuses and configurations of the bus monitor 122 is captured. For example, the bus monitor 122 intercepts the bus signals on the interface of the bus 113, and the bus signals may be very complicated, and thus an extraction step to obtain the statuses and configurations is required (e.g. step S806).

In step S806, the statuses and configurations of the bus monitor 122 are extracted by the restoring/extracting state module 141.

In step S808, the contents of the extracted statuses and configurations are saved (i.e. “pushed”) into the memory 123.

In step S810, it is determined whether the traditional BIST logic results in a pass or a failure. For example, the determination of the traditional BIST logic is performed on-the-fly based on the pre-stored test vectors. If the result of the BIST is a pass, step S814 is performed. If the result of the BIST is a failure, step S812 is performed.

In step S812, when the BIST result is a failure, the BIST circuit 121 sends an interrupt signal to the CPU and software processes, and it may indicate that a problem may occur in the bus apparatus 110 and/or the bus monitor 122, and that the CPU may take appropriate action to the bus failure.

In step S814, the contents of the extracted statuses and configuration are retrieved (i.e. “popped”) from the memory 123.

In step S816, the statuses and configuration of the bus apparatus 110 is restored.

In step s818, the bus monitor is recovered to the normal state. For example, during the BIST, the bus monitor 122 may be paused or the bus interface between the bus 113 and the bus monitor 122 may be paused. Thus, after the BIST is completed, the bus monitor 122 is recovered to the normal state to detect bus signals on the interface of the bus 113.

In step S820, BIST is done.

In view of the above, a test controller and a BIST method are provided in the disclosure. The test controller and the BIST method are capable of actively raising an alarm of a bus interface malfunction using the BIST circuit while the bus apparatus is in operation, thereby achieving on-the-fly bus monitoring. In addition, the test controller is also capable of performing self-health checking when the bus agent is busy.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test controller, comprising:
a test circuit for testing functionality of a bus apparatus, wherein the bus apparatus comprises a bus connected between a bus agent and a first bus matrix; and
a bus monitor, for monitoring bus signals on an interface of the bus,
wherein when a test is enabled during operation of the bus apparatus, the test circuit saves statuses and configurations of the bus apparatus that are extracted from the bus signals into a memory,
wherein when the test is completed, the test circuit restores the statuses and configurations of the bus apparatus from the memory.

2. The test controller as claimed in claim 1, wherein the test is performed according to a plurality of pre-stored test vectors in the memory.

3. The test controller as claimed in claim 1, wherein when the test results in a failure, the test circuit sends an interrupt signal to a processor connected to the bus.

4. The test controller as claimed in claim 2, wherein the test circuit comprises:
an extracting/restoring state module, configured to extract the statuses and configuration of the bus apparatus from the bus signals from the bus monitor; and
a controller, configured to save the statuses and configurations of the bus apparatus into the memory, and loads the pre-stored test vectors from the memory to perform the test.

5. The test controller as claimed in claim 1, wherein the test circuit sends a first control signal to the bus apparatus to control the bus to pause for a time period when the test is being performed.

6. The test controller as claimed in claim 1, wherein the test circuit sends a first control signal to the bus apparatus to direct the interface of the bus to a second bus matrix and control the bus interface between the bus and the bus monitor to pause when the test is being performed.

7. The test controller as claimed in claim 1, wherein the bus apparatus further comprises an arbiter configured to direct a monitoring interface of the bus to connect to another test controller when the test is being performed.

8. The test controller as claimed in claim 1, wherein the bus apparatus further comprises an arbiter configured to receive a busy notification signal from the bus agent, and inform the bus monitor of a busy state of the bus agent,
wherein the bus monitor temporarily stops monitoring the interface of the bus when the BIST is being performed or the bus agent is in the busy state.

9. A test method for use in a test controller, wherein the test controller comprises a test circuit for testing the functionality of a bus apparatus; and a bus monitor, for monitoring bus signals on an interface of the bus, wherein the bus apparatus comprises a bus connected between a bus agent and a first bus matrix, the method comprising:
when a test is enabled during operation of the bus apparatus, utilizing the test circuit to save statuses and configurations of the bus apparatus that are extracted from the bus signals into a memory,
when the test is completed, utilizing the test circuit to restore the statuses and configurations of the bus apparatus from the memory.

10. The test method as claimed in claim 9, wherein the test is performed according to a plurality of pre-stored test vectors in the memory.

11. The test method as claimed in claim 9, further comprising:
when a result of the test is failure, utilizing the test circuit to send an interrupt signal to a processor connected to the bus.

12. The test method as claimed in claim 10, wherein the test circuit comprises:
an extracting/restoring state module, configured to extract the statuses and configuration of the bus apparatus from the bus signals from the bus monitor; and
a controller, configured to save the statuses and configurations of the bus apparatus into the memory, and to load the pre-stored test vectors from the memory to perform the test.

13. The test method as claimed in claim 9, further comprising:
utilizing the test circuit to send a first control signal to the bus apparatus to control the bus to pause for a time period when the test is being performed.

14. The test method as claimed in claim 9, further comprising:
utilizing the test circuit to send a first control signal to the bus apparatus to direct the interface of the bus to a second bus matrix and control the bus interface between the bus and the bus monitor to pause when the test is being performed.

15. The test method as claimed in claim 9, further comprising:
utilizing an arbiter of the bus apparatus to direct a monitoring interface of the bus to connect to another test controller when the test is being performed.

16. The test method as claimed in claim 9, further comprising:
utilizing an arbiter of the bus apparatus to receive a busy notification signal from the bus agent, and inform the bus monitor of a busy state of the bus agent; and
utilizing the bus monitor to temporarily stop monitoring the interface of the bus when the test is being performed or the bus agent is in the busy state.

17. A test controller, comprising:
a test circuit configured to test functionality of a bus apparatus; and
a bus monitor, for monitoring bus signals on an interface of a bus of the bus apparatus,
wherein the test circuit is further configured to detect a status of the bus monitor, and determine whether to raise an alarm signal according to the status of the bus monitor.

18. The test controller as claimed in claim 17, wherein when a test is performed on the bus monitor and the bus apparatus during operation of the bus apparatus, the test circuit saves statuses and configurations of the bus apparatus that are extracted from the bus signals into a memory of the test circuit,
wherein when the test is completed, the test circuit restores the statuses and the configurations of the bus apparatus from the memory.

19. The test controller as claimed in claim 18, wherein when the test results in a failure, the test circuit sends the alarm signal to a processor on the bus.

20. The test controller as claimed in claim 18, wherein the test is performed according to a plurality of pre-stored test vectors in the memory.
